(19) United States
(12) Patent Application Publication
(10) Pub. No.: US 2012/0119188 A1
(43) Pub. Date: May 17, 2012

(54) SEMICONDUCTOR APPARATUS MANUFACTURING METHOD AND SEMICONDUCTOR APPARATUS

(75) Inventors: Yoshinori Sawado, Kai (JP); Katsumi Yoshizawa, Koshu (JP)

(73) Assignee: PIONEER CORPORATION, Kanagawa (JP)

(21) Appl. No.: 13/384,827

(22) PCT Filed: Jul. 24, 2009
(86) PCT No.: PCT/JP2009/063280

§ 371 Date: Jan. 19, 2012

(51) Int. Cl. H01L 33/04

(52) U.S. Cl. 257/13; 438/47; 257/E33.005

(57) ABSTRACT

A semiconductor apparatus manufacturing method is a method of manufacturing a semiconductor apparatus having a peak wavelength of PL emission of greater than or equal to 1.2 μm at a temperature of 300K. The manufacturing method is provided with: a first forming process of forming a buffer layer (120) including GaAs on a semiconductor substrate (110); a second forming process of making quantum dots (131) including InAs self-form on the formed buffer layer; and a third forming process of forming a cap layer (140) including GaAs to cover the formed quantum dots. A second growth temperature is less than a first growth temperature, wherein the first growth temperature is a temperature in making the quantum dots self-form in the second forming process and the second growth temperature is a temperature in forming the cap layer in the third forming process.

### TECHNICAL FIELD

The present invention relates to a method of manufacturing a semiconductor apparatus including quantum dots formed on a semiconductor substrate, and a semiconductor apparatus manufactured by the manufacturing method.

### BACKGROUND ART

As a semiconductor apparatus manufactured by this type of manufacturing method, there is a semiconductor apparatus provided with a gallium arsenide (GaAs) substrate. Moreover, the semiconductor apparatus manufactured by this type of manufacturing method is applied, for example, to optical fiber transmission. Here, in the optical fiber transmission, a semiconductor apparatus for emitting light with a wavelength of 1250 nanometers (nm) to 1650 nm is required. Thus, in this type of manufacturing method, for example, a semiconductor apparatus provided with the GaAs substrate for emitting light with a wavelength of greater than or equal to 1200 nm is manufactured.

For example, a patent document 1 describes a manufacturing method in which indium arsenide (InAs) is supplied on a GaAs layer averagely at a supply of 0.002 monolayer (ML) per second to form quantum dots, in which a first carrier confinement layer including InₓGa₁₋ₓAs (0.1≦x≦0.17) is formed to cover the quantum dots, and in which a second carrier confinement layer including GaAs is formed on the first carrier confinement layer.

Alternatively, a patent document 2 describes a manufacturing method in which a GaAs buffer layer is formed on a GaAs substrate at 580° C., in which InAs quantum dots are formed on the buffer layer at 500° C. at a growth rate of 0.015 ML per second, and in which a GaAs cap layer is formed at 500° C. and then annealed at 580° C.

### Prior Art Document

### Patent Document

Patent document 1: Japanese Patent Application Laid Open No. 2009-10425
Patent document 2: Japanese Translation of PCT international application (Tokuhyo) No. 2005-534164

### Disclosure of Invention

### Subject to be Solved by the Invention

However, in the technology described in the patent document 1, it is hard to control the supply of InAs, and there is a possibility that it is hard to ensure satisfactory reproducibility, which is technically problematic. Moreover, in the technology described in the patent document 2, there is such a technical problem that the annealing causes In to diffuse in the cap layer, which likely reduces a quantum confinement effect for the quantum dots.

In view of the aforementioned problem, it is therefore an object of the present invention to provide a semiconductor apparatus manufacturing method and a semiconductor apparatus capable of improving the reproducibility and improving the quantum confinement effect.

### Means for Solving the Subject

The above object of the present invention can be achieved by a method of manufacturing a semiconductor apparatus in which a peak wavelength of PL (Photoluminescence) emission is greater than or equal to 1.2 μm (micrometers) at a temperature of 300K (Kelvin), the method provided with: a first forming process of forming a buffer layer including GaAs on a semiconductor substrate; a second forming process of making quantum dots including InAs self-form on the formed buffer layer; and a third forming process of forming a cap layer including GaAs to cover the formed quantum dots, a second growth temperature being lower than a first growth temperature, the first growth temperature being a temperature in making the quantum dots self-form in the second forming process, the second growth temperature being a temperature in forming the cap layer in the third forming process.

According to the method of manufacturing the semiconductor apparatus of the present invention, the manufacturing method is a method of manufacturing a semiconductor apparatus in which the peak wavelength of the PL emission is greater than or equal to 1.2 μm at a temperature of 300K (i.e. at room temperature). The manufacturing method is provided with the first to third forming processes.

In the first forming process, the buffer layer including GaAs is formed on the semiconductor substrate such as a GaAs substrate. In the second forming process, the quantum dots including InAs self-form on the formed buffer layer. In the third forming process, the cap layer including GaAs is formed to cover the formed quantum dots.

Here, the first growth temperature which is a temperature in making the quantum dots self-form in the second forming process is, for example, 520° C. On the other hand, the second growth temperature which is a temperature in forming the cap layer in the third forming process is, for example, 450° C. In other words, in the method of manufacturing the semiconductor apparatus of the present invention, the second growth temperature is lower than the first growth temperature.

According to a study by the present inventors, the following is found; namely, if the semiconductor apparatus provided with the GaAs substrate is used to obtain the PL emission with a peak wavelength of greater than or equal to 1.3 μm at a temperature of 300K, in many cases, it adopts a structure for covering the quantum dots composed of InAs with the cap layer composed of InGaAs, for example, as described in the patent document 1 described above.

On the other hand, in the case where the quantum dots composed of InAs is covered with the cap layer composed of GaAs, for example, as described in the patent document 2 described above, it is estimated that simply by covering the quantum dots composed InAs with the cap layer composed of GaAs, the peak wavelength of the PL emission will be shorten (i.e. the peak wavelength becomes less than 1.2 μm at room temperature). Thus, in the patent document 2, as described above, the annealing is performed at 580° C. after the formation of the cap layer.

Here, with reference to the temperature of the annealing, in the patent document 2, it is estimated that In diffuses in the cap layer in the annealing. In other words, in the patent document 2, substantially, it is estimated to adopt the structure for covering the quantum dots with the cap layer composed of InGaAs. Alternatively, it is estimated that Ga diffuses in the quantum dots in the annealing and that the quantum dots are mixed crystals of InAs and InGaAs. Then, the quantum confinement effect for the quantum dots is likely reduced.

In the present invention, however, the second growth temperature which is the temperature in forming the cap layer in the third forming process is set to be lower than the first growth temperature which is the temperature in making the quantum dots self-form in the second forming process. Thus, since In does not diffuse in the cap layer, it is possible to improve the quantum confinement effect for the quantum dots, in comparison with the case where the quantum dots are covered with the cap layer composed of InGaAs.

In addition, since it is easier to control the first and second growth temperatures than controlling the supply of the material (e.g. InAs, etc.), the reproducibility can be improved.

In one aspect of the method of manufacturing the semiconductor apparatus of the present invention, the first growth temperature is set to make the peak wavelength longer.

According to this aspect, it is possible to certainly make the peak wavelength of the PL emission longer (i.e. to set the peak wavelength to be greater than or equal to 1.2 μm at room temperature) and it is practically very useful.

In another aspect of the method of manufacturing the semiconductor apparatus of the present invention, the first growth temperature is greater than or equal to 490° C. and less than or equal to 530° C., a growth rate of the quantum dots in the second forming process is greater than or equal to 0.02 ML/s (monolayer/second) and less than or equal to 0.4 ML/s, the second growth temperature is greater than or equal to 420° C. and less than or equal to 480° C., and a growth rate of the cap layer in the third forming process is greater than or equal to 0.1 ML/s and less than or equal to 0.5 ML/s.

According to this aspect, it is possible to set the peak wavelength of the PL emission to be about 1.3 μm at room temperature. By this, the semiconductor apparatus manufactured by the manufacturing method can be applied to optical fiber transmission.

In another aspect of the method of manufacturing the semiconductor apparatus of the present invention, an irradiance of an As molecular beam in the second forming process is 1×10⁻⁵ Torr.

According to this aspect, it is possible to appropriately form the quantum dots such that the peak wavelength of the PL emission is about 1.3 μm at room temperature and it is practically very useful.

In another aspect of the method of manufacturing the semiconductor apparatus of the present invention, it is further provided with a temperature falling process of reducing a temperature of the semiconductor substrate at a rate of greater than or equal to 20° C./min and less than or equal to 35° C./min, after the second forming process and before the third forming process.

According to this aspect, it is possible to increase the peak intensity of the PL emission and it is practically very useful.

In another aspect of the method of manufacturing the semiconductor apparatus of the present invention, a diameter of the formed quantum dots is greater than or equal to 30 nm and less than or equal to 60 nm, and height of the formed quantum dots is less than or equal to 15 nm.

According to this aspect, it is possible to set the peak wavelength of the PL emission to be about 1.3 μm at room temperature. Incidentally, the diameter and height of the quantum dots are based on values measured by an atomic force microscope (AFM) before the formation of the cap layer.

The above object of the present invention can be also achieved by a first semiconductor apparatus provided with quantum dots formed by the method of manufacturing the semiconductor apparatus of the present invention described above (including its various aspects).

According to the first semiconductor apparatus of the present invention, since it is provided with the quantum dots formed by the method of manufacturing the semiconductor apparatus of the present invention described above, it is possible to provide the semiconductor apparatus having a relatively high quantum confinement effect. In addition, due to relatively high reproducibility in the manufacturing process, it is possible to reduce cost for manufacturing the semiconductor apparatus and it is practically very useful.

The above object of the present invention can be also achieved by a second semiconductor apparatus in which a peak wavelength of PL emission is greater than or equal to 1.2 μm and less than or equal to 1.3 μat a temperature of 300K, the semiconductor apparatus provided with: a semiconductor substrate; and an active layer formed on the semiconductor substrate, the active layer including: a buffer layer including GaAs; quantum dots including InAs and formed on the buffer layer; and a cap layer including GaAs and formed to cover the quantum dots, volume of at least one portion of the quantum dots being greater than or equal to 800 nm³ and less than or equal to 3000 nm³.

According to the second semiconductor apparatus of the present invention, the second semiconductor apparatus is a semiconductor apparatus in which the peak wavelength of the PL emission is greater than or equal to 1.2 μm and less than or equal to 1.3 μm at a temperature of 300K. The semiconductor apparatus is provided with: the semiconductor substrate such as a GaAs substrate; and the active layer formed on the semiconductor substrate.

The active layer is provided with: the buffer layer including GaAs; the quantum dots including InAs and formed on the buffer layer; and the cap layer including GaAs and formed to cover the quantum dots.

Here, the volume of at least one portion of the plurality of quantum dots formed is greater than or equal to 800 nm3 and less than or equal to 3000 nm³. Incidentally, the volume of the quantum dots is a value obtained on the basis of an image observed by a transmission electron microscope (TEM) under the assumption that the quantum dots have a conic shape.

According to the second semiconductor apparatus of the present invention, it is possible to set the peak wavelength of the PL emission to be about 1.3 μm at room temperature. Thus, the semiconductor apparatus can be applied to the optical fiber transmission. Moreover, in order to set the volume of at least one portion of the plurality of quantum dots formed to be greater than or equal to 800 nm³ and less than or equal to 3000 nm³, the quantum dots are formed by the method of manufacturing the semiconductor apparatus of the present invention described above. Therefore, it is possible to provide the semiconductor apparatus having the relatively high quantum confinement effect. In addition, due to the relatively high reproducibility in the manufacturing process, it is possible to reduce the cost for manufacturing the semiconductor apparatus and it is practically very useful.

In one aspect of the second semiconductor apparatus of the present invention, thickness of the cap layer is greater than height of the quantum dots.

According to this aspect, it is possible to certainly obtain the quantum confinement effect and it is practically very useful.

The operation and other advantages of the present invention will become more apparent from Mode for Carrying Out the Invention explained below.

### BRIEF DESCRIPTION OF DRAWINGS

FIG. 1 is a process chart showing one portion of a process of a forming method in an embodiment of the present invention.

FIG. 2 is a process chart showing a buffer layer forming process following the process in FIG. 1.

FIG. 3 is a process chart showing a quantum dot forming process following the process in FIG. 2.

FIG. 4 is a process chart showing a cap layer forming process following the process in FIG. 3.

FIG. 5 is one example of experimental values showing a relation between a substrate temperature and a quantum dot diameter in the case of a growth rate of 0.04 ML/s for each amount of growth of an InAs layer.

FIG. 6 is one example of experimental values showing a relation between substrate temperature and quantum dot height in the case of a growth rate of 0.04 ML/s for each amount of growth of the InAs layer.

FIG. 7 is one example showing experimental data indicating a change in peak of PL emission if the growth temperature of the cap layer is changed.

FIG. 8 is another example showing experimental data indicating the change in the peak of the PL emission if the growth temperature of the cap layer is changed.

FIG. 9 is one example of experimental data indicating the change in the peak of the PL emission if the growth temperature of the cap layer is fixed and the growth temperature of quantum dots is changed.

FIG. 10(a) is one example of experimental data indicating the change in the peak of the PL emission if either the growth temperature of the cap layer or the growth temperature of the quantum dots is changed, and FIG. 10(b) is a table showing growth conditions corresponding to the experimental data shown in FIG. 10(a).

FIG. 11 is one example of experimental data indicating the change in the peak of the PL emission if a substrate temperature falling rate between the quantum dot forming process and the cap layer forming process is changed.

FIG. 12 is one example of experimental data indicating the change in the peak of the PL emission if film thickness of the cap layer is changed.

FIG. 13 is one example of experimental data indicating a quantum dot size and volume based on a TEM image.

### MODE FOR CARRYING OUT THE INVENTION

Hereinafter, with reference to the drawings, an explanation will be given on an embodiment of each of a semiconductor apparatus manufacturing method and a semiconductor apparatus manufactured by the manufacturing method of the present invention. Incidentally, in the following drawings, the scale varies for each layer and each member in order to make each layer and each member large enough to be recognized on the drawings.

### (Method of Manufacturing Semiconductor Apparatus)

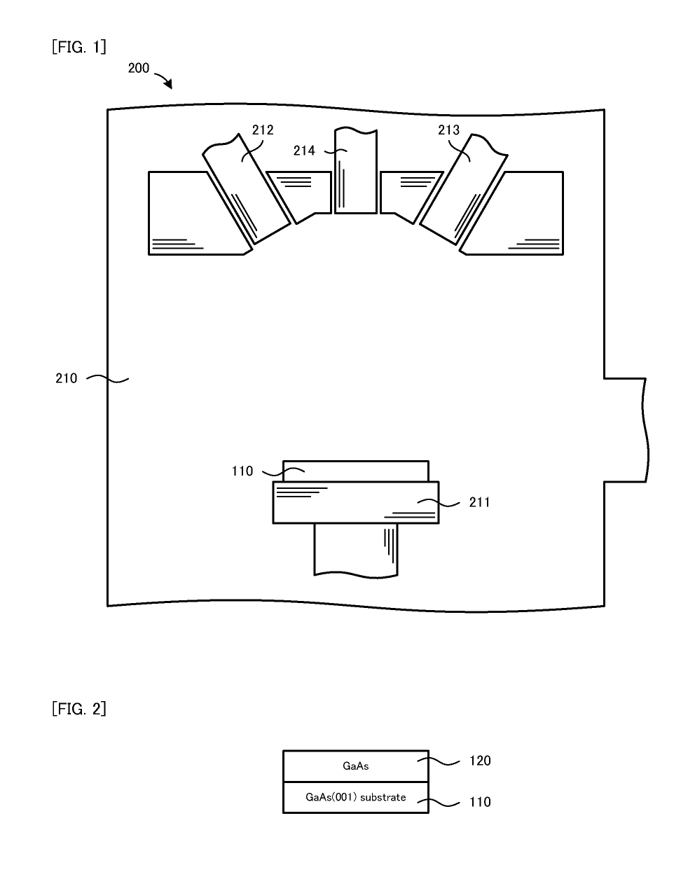

The method of manufacturing the semiconductor apparatus in the embodiment will be explained with reference to FIG. 1 to FIG. 4.

Firstly, as shown in FIG. 1, on a substrate rotating and heating mechanism 211 in a growth chamber 201 of a molecular beam epitaxial (MBE) growth apparatus 200, a GaAs substrate 110 is disposed as one example of the “semiconductor substrate” of the present invention. FIG. 1 is a process chart showing one portion of a process of a forming method in the embodiment.

Incidentally, FIG. 1 omits the detailed members of the MBE growth apparatus 200 as occasion demands and shows only members directly related.

Then, the growth chamber 201 is depressurized, for example, to less than or equal to 1×10⁻⁹ Torr. Then, the GaAs substrate 110 is irradiated with As from an evaporation source 214, for example, at an irradiance of about 1×10⁻⁵ Torr. Under the As irradiation, the substrate temperature of the GaAs substrate 110 is heated, for example, to about 600 degrees C. by the substrate rotating and heating mechanism 211 to clean the surface of the GaAs substrate.

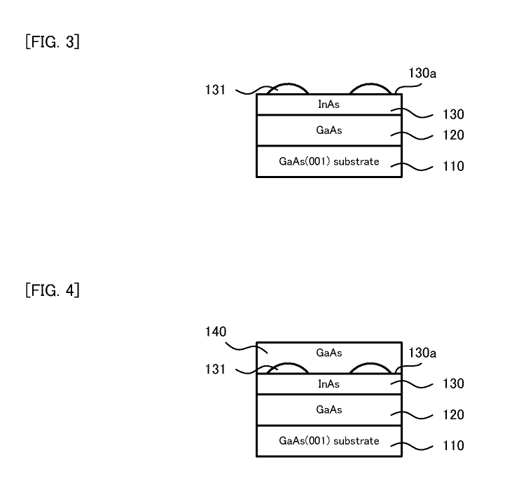

Then, the substrate temperature is set, for example, to 560 degrees C. Then, the GaAs substrate 110 is irradiated with As and Ga from the evaporation sources 214 and 212, respectively, for example, for about 10 minutes. As a result, as shown in FIG. 2, a GaAs buffer layer 120 is formed on a (001) surface of the GaAs substrate 110. FIG. 2 is a process chart showing a buffer layer forming process following the process in FIG. 1. In FIG. 2, the illustration of the members associated with the MBE growth apparatus 200 is omitted (the same shall apply hereinafter).

Incidentally, the irradiance of each of As and Ga is set, for example, as an irradiance in which the GaAs buffer layer 120 can be grown at a growth rate of about 1 ML/s. The thickness of the GaAs layer formed is, for example, about 150 nm.

Then, the substrate temperature is set to be greater than or equal to 490° C. and less than or equal to 530° C., as one example of the “first growth temperature” of the present invention. Then, the GaAs buffer layer 120 is irradiated with As and In from the evaporation sources 214 and 213, respectively. Here, with the growth of an InAs layer 130, a plurality of quantum dots 131 including InAs are formed by self-assembled growth on an upper surface 130a of the InAs layer 130. As a result, as shown in FIG. 3, the InAs layer 130 is formed on the GaAs buffer layer 120. FIG. 3 is a process chart showing a quantum dot forming process following the process in FIG. 2.

Incidentally, the irradiance of each of As and In is set as an irradiance in which the InAs layer 130 can be grown at a growth rate of greater than or equal to 0.02 ML/s and less than or equal to 0.4 ML/s. The amount of growth of the InAs layer 130 is, for example, about 1.8 ML. Moreover, the diameter of the quantum dots 131 is greater than or equal to 30 nm and less than or equal to 60 nm. The height of the quantum dots 131 is less than or equal to 15 nm.

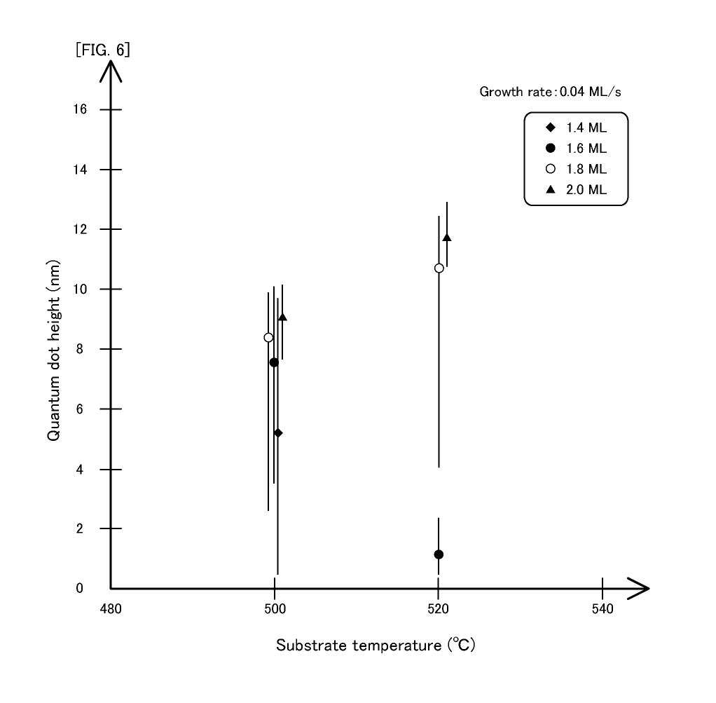

Here, the formed quantum dots 131 will be explained with reference to FIG. 5 and FIG. 6. FIG. 5 is one example of experimental values showing a relation between the substrate temperature and the quantum dot diameter in the case of a growth rate of 0.04 ML/s for each amount of growth of the InAs layer 130. FIG. 6 is one example of experimental values showing a relation between the substrate temperature and the quantum dot height in the case of a growth rate of 0.04 ML/s for each amount of growth of the InAs layer 130.

Incidentally, in FIG. 5 and FIG. 6, for convenience, symbols are shown at substrate temperatures, each of which is slightly shifted from true substrate temperature, so as not to overlap one another. Moreover, vertical lines added to the symbols in the drawings show errors.

For example, focusing on experimental values with a growth amount of the InAs layer 130 of 1.8 ML (“∘” in the drawings), it is clear that when the substrate temperature is greater than or equal to 490° C. and less than or equal to 530° C., the diameter of the quantum dots 131 is in a range of greater than or equal to 30 nm and less than or equal to 60 nm (refer to FIG. 5) and the height of the quantum dots 131 is less than or equal to 15 nm (refer to FIG. 6). Incidentally, the experimental values shown in FIG. 5 and FIG. 6 are values measured by an AFM before the formation of a GaAs cap layer 140.

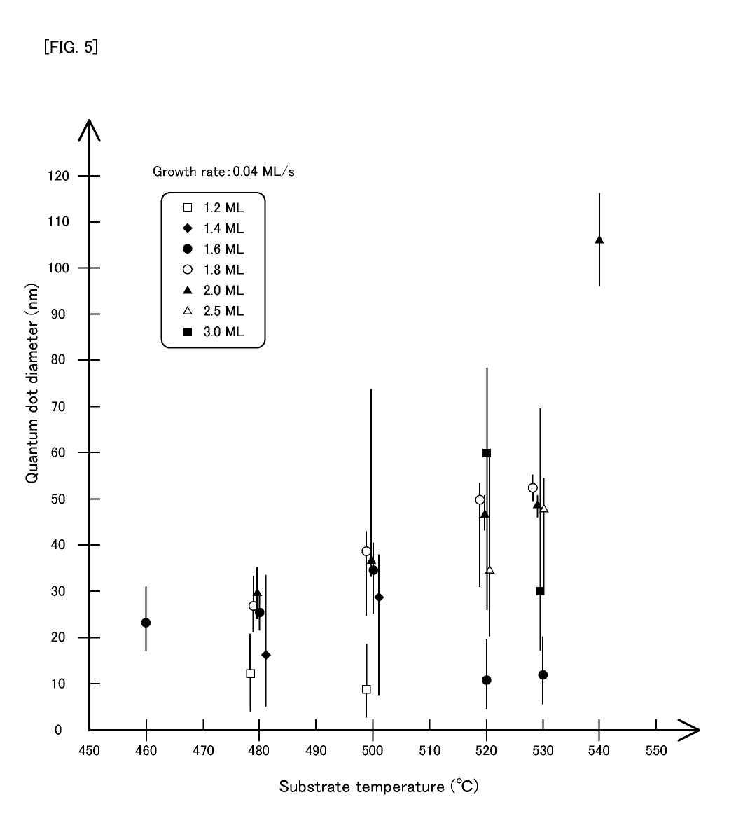

Then, the substrate temperature is reduced to a temperature which is greater than or equal to 420° C. and less than or equal to 480° C., as one example of the “second growth temperature” of the present invention. Here, a substrate temperature falling rate is in a range of greater than or equal to 20° C./min and less than or equal to 35° C./min. Then, to cover the quantum dots 131, As and Ga are applied from the evaporation sources 214 and 213, respectively. As a result, as shown in FIG. 4, the GaAs cap layer 140 is formed. FIG. 4 is a process chart showing a cap layer forming process following the process in FIG. 3.

Incidentally, the irradiance of each of As and Ga is set as an irradiance in which the GaAs cap layer 140 can be grown at a growth rate of greater than or equal to 0.1 ML/s and less than or equal to 0.5 ML/s. The thickness of the cap layer 140 formed is, for example, 24 nm.

Incidentally, a portion from the GaAs substrate 110 to the GaAs cap layer 140 constitutes one example of the “semiconductor apparatus” of the present invention. Moreover, the “buffer layer forming process”, the “quantum dot forming process”, and the “cap layer forming process” in the embodiment are one example of the “first forming process”, the “second forming process”, and the “third forming process” of the present invention, respectively.

### (Semiconductor Apparatus)

Next, with reference to FIG. 7 to FIG. 13, an explanation will be given on the semiconductor apparatus in the embodiment manufactured by the aforementioned manufacturing method.

Firstly, the semiconductor apparatus in the embodiment and a semiconductor apparatus in a comparative example will be explained with reference to FIG. 7. Here, regarding the semiconductor apparatus in the embodiment, the growth tempearture of the quantum dots 131 (i.e. the “first growth temperature” of the present invention) is 510° C. and the growth temperature of the GaAs cap layer 140 (i.e. the “second growth temperature” of the present invention) is 450° C. On the other hand, regarding the semiconductor apparatus in the comparative example, the growth temperature of the quantum dots 131 is 510° C. and the growth temperature of the GaAs cap layer 140 is 510° C. Incidentally, other conditions are all the same.

FIG. 7 is one example showing experimental data indicating a change in the peak of PL emission if the growth temperature of the cap layer is changed. Incidentally, in FIG. 7, the spectrum of the PL emission at room temperature of the semiconductor apparatus in the embodiment is indicated by a solid line, and the spectrum of the PL emission at room temperature of the semiconductor apparatus in the comparative example is indicated by a dotted line.

As shown in FIG. 7, in the semiconductor apparatus in the embodiment, a peak of the PL emission appears near a wavelength of 1.3 μm. On the other hand, in the semiconductor apparatus in the comparative example, there is no peak of the PL emission at a wavelength of greater than or equal to 1.2 μm. In other words, it is clear that by setting the growth temperature of the GaAs cap layer 140 to be lower than the growth temperature of the quantum dots, it is possible to make the peak wavelength of the PL emission longer (i.e. to set the peak wavelength to be greater than or equal to 1.2 μm at room temperature).

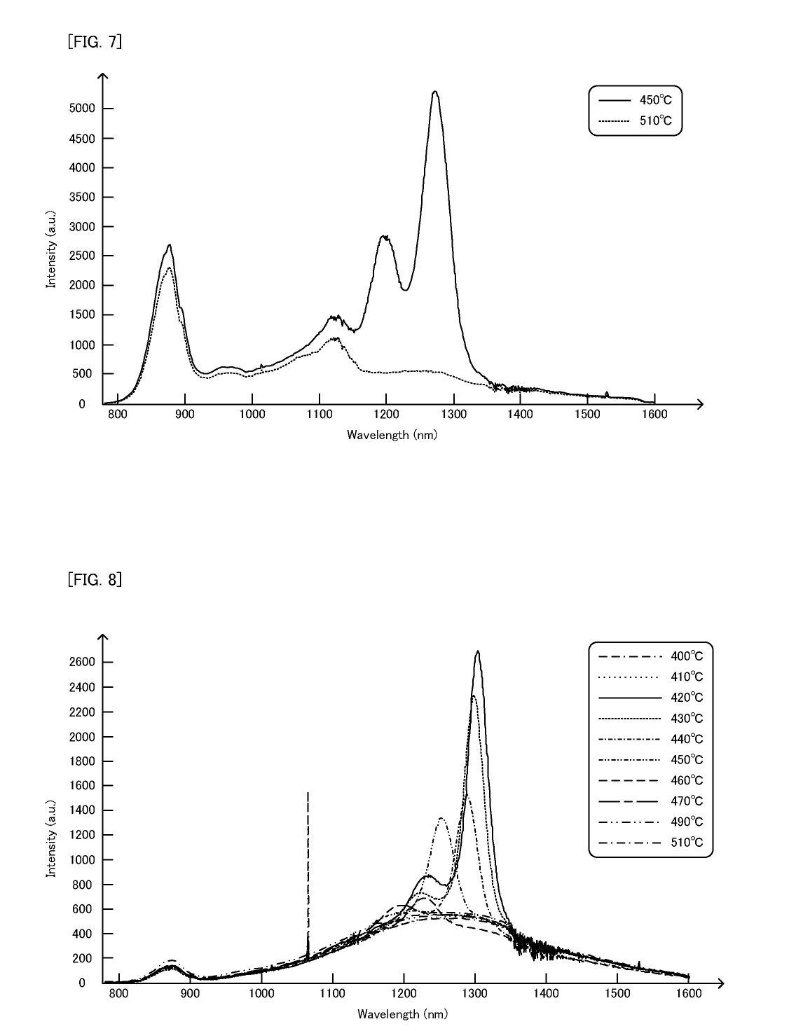

Next, with reference to FIG. 8, an explanation will be given on the growth temperature of the GaAs cap layer 140 which can make the peak wavelength of the PL emission longer. FIG. 8 is another example showing experimental data indicating the change in the peak of the PL emission if the growth temperature of the cap layer is changed. Incidentally, conditions other than the growth temperature of the GaAs cap layer 140 are all the same.

As shown in FIG. 8, it is clear that if the growth temperature of the GaAs cap layer 140 is greater than or equal to 420° C. and less than or equal to 480° C., a peak of the PL emission appears at a wavelength of greater than or equal to 1.2 μm. Incidentally, FIG. 8 does not show experimental data corresponding to 480° C.; however, according to a study by the present inventors, it is found that even if the growth temperature of the GaAs cap layer 140 is set to around 480° C., a peak of the PL emission appears at a wavelength of greater than or equal to 1.2 μm.

Moreover, it is also clear that if the growth temperature of the GaAs cap layer 140 is in a range of greater than or equal to 420° C. and less than or equal to 510° C., the peak wavelength of the PL emission from the ground level of the quantum dots 131 becomes longer as the growth temperature of the GaAs cap layer 140 falls. Moreover, it is clear that the intensity of the PL emission from the ground level of the quantum dots 131 becomes higher as the growth temperature of the GaAs cap layer 140 falls.

As the reason why the peak of the PL emission does not appear at a wavelength of greater than or equal to 1.2 μm if the growth temperature of the GaAs cap layer 140 is less than 420° C., the followings can be considered: (1) indium surface segregation is inhibited; (ii) migration by thermal energy is not performed sufficiently and lattice mismatch of GaAs/InAs is not eased; and (iii) emission energy is absorbed due to an interband level caused by dislocation or rearrangement in the GaAs cap layer 140.

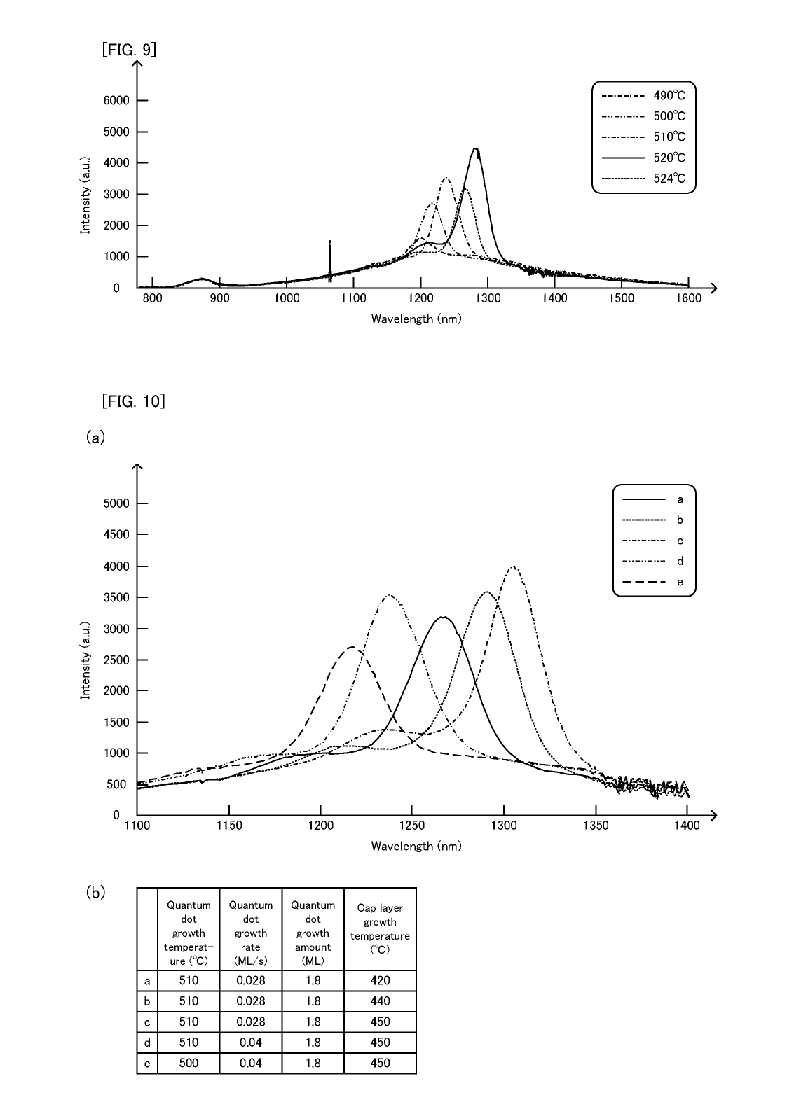

Next, with reference to FIG. 9, an explanation will be given on the PL emission if the growth temperature of the GaAs cap layer 140 is fixed to 450° C. and the growth temperature of the quantum dots 131 is changed. FIG. 9 is one example of experimental data indicating the change in the peak of the PL emission if the growth temperature of the cap layer is fixed and the growth temperature of quantum dots is changed.

Incidentally, conditions for forming the InAs layer 130 other than the growth temperature of the quantum dots 131 are a growth rate of 0.04 ML/s and a growth amount of 1.8 ML. Moreover, after the formation of the quantum dots 131, the GaAs cap layer 140 was formed after the substrate temperature was set to 450° C. while As was applied. The wavelength of an excitation light source applied to the semiconductor apparatus is 532 nm, and incident intensity is 0.2 mW.

As shown in FIG. 9, it is clear that as the growth temperature of the quantum dots 131 rises, the peak wavelength of the PL emission at room temperature becomes longer. Moreover, the intensity of the PL emission from the ground level of the quantum dots 131 increases as the growth temperature of the quantum dots 131 rises. Incidentally, there is such a tendency that the quantum dots 131 increase in size as the growth temperature of the quantum dots 131 rises.

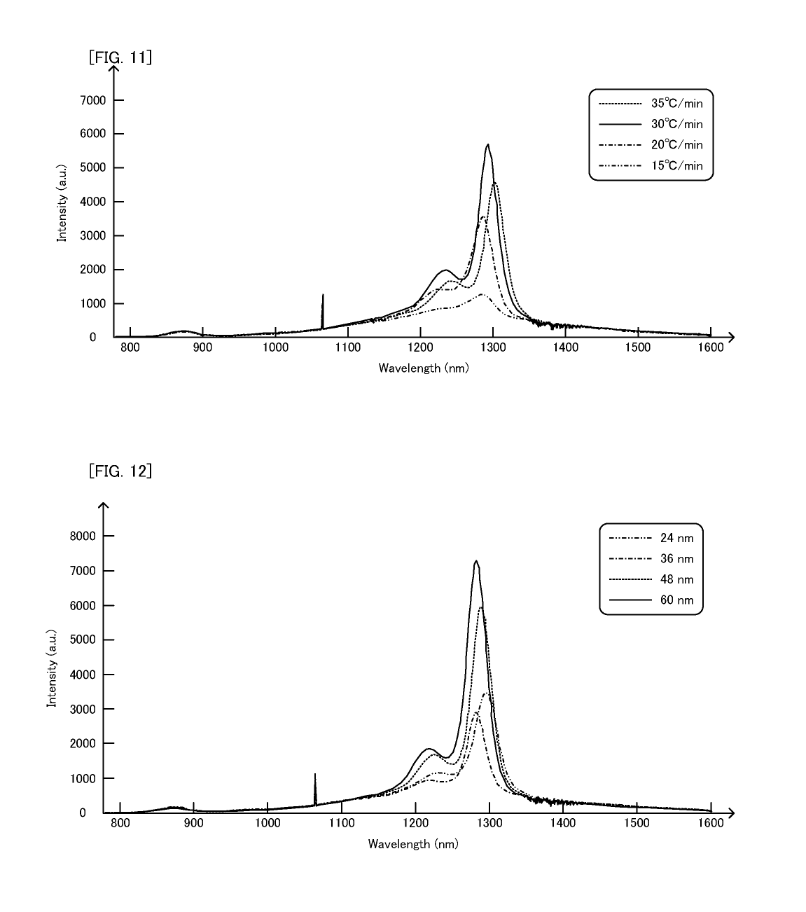

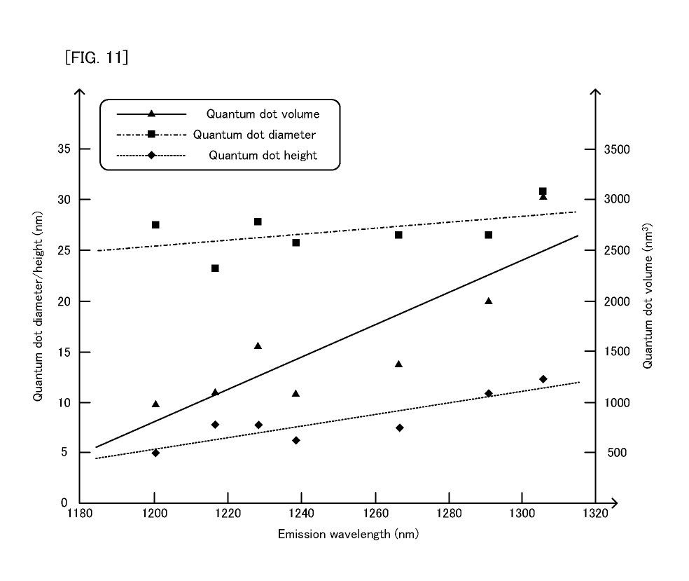

Incidentally, in FIG. 8 and FIG. 9, there is a peak of the PL emission near a wavelength of 1060 nm. This is laser light, which is applied for the measurement of the PL emission characteristics, detected as a noise (the same shall apply to FIG. 11 and FIG. 12).

Next, as shown in FIGS. 10, it is clear that the peak wavelength of the PL emission can be controlled in a range of 1.2 μm to 1.3 μm by appropriately setting the conditions for forming the quantum dots 131 and the growth temperature of the GaAs cap layer 140. FIG. 10(a) is one example of experimental data indicating the change in the peak of the PL emission if either the growth temperature of the cap layer or the growth temperature of the quantum dots is changed, and FIG. 10(b) is a table showing growth conditions corresponding to the experimental data shown in FIG. 10(a).

Incidentally, the PL emission spectrum having a peak wavelength of 1.3 μm (i.e. a photon energy of 0.95 eV) has a half-width of 26 meV.

Then, with reference to FIG. 11, an explanation will be given on a relation between a temperature falling rate when the substrate temperature is reduced to a temperature for forming the GaAs cap layer 140 after the formation of the quantum dots 131 and the intensity of the PL emission. FIG. 11 is one example of experimental data indicating the change in the peak of the PL emission if the substrate temperature falling rate between the quantum dot forming process and the cap layer forming process is changed. Incidentally, the growth temperature of the quantum dots 131 is 510° C., the growth rate of the quantum dots 131 is 0.028 ML/s, and the growth amount of the quantum dots 131 is 1.8 ML. Moreover, the growth temperature of the GaAs cap layer 140 is 420° C.

As shown in FIG. 11, it is clear that due to the change in the temperature falling rate, the intensity of the PL emission changes. In other words, by appropriately controlling the temperature falling rate, it is possible to increase the intensity of the PL emission.

Next, with reference to FIG. 12, an explanation will be given on a relation between the thickness of the GaAs cap layer 140 and the intensity of the PL emission. FIG. 12 is one example of experimental data indicating the change in the peak of the PL emission if the film thickness of the cap layer is changed. Incidentally, the growth temperature of the quantum dots 131 is 510° C., the growth rate of the quantum dots 131 is 0.028 ML/s, and the growth amount of the quantum dots 131 is 1.8 ML. Moreover, the growth temperature of the GaAs cap layer 140 is 430° C. and the growth rate of the GaAs cap layer 140 is 0.2 ML/s.

As shown in FIG. 12, it is clear that due to the change in the thickness of the GaAs cap layer 140, the intensity of the PL emission changes. This is because if the GaAs cap layer 140 increases in thickness, the number of electron-hole pairs generated in GaAs increases. In other words, by appropriately controlling the thickness of the GaAs cap layer 140, it is possible to increase the intensity of the PL emission.

Incidentally, it is found from the study by the present inventors that if the GaAs cap layer 140 increases in thickness, blue shift occurs near the peak of the PL emission due to a distortion in GaAs.

Next, with reference to FIG. 13, the size and the like of the quantum dots 131 based on a TEM image will be explained. FIG. 13 is one example of experimental data indicating the quantum dot size and volume based on the TEM image.

As shown in FIG. 13, it is clear that when the peak wavelength of the

PL emission is in a range of 1.2 μm to 1.3 μm, the volume of the quantum dots 131 is 800 nm³ to 3000 nm³, the diameter is 20 nm to 30 nm, and the height is less than or equal to 15 nm. Incidentally, the volume of the quantum dots 131 is a value obtained under the assumption that the quantum dots have a conic shape.

Here, the values measured by the AFM shown in FIG. 5 and FIG. 6 and the values measured by a TEM shown in FIG. 13 are different from each other; however, this is due to a difference in the measurement method. It is also found from the study by the present inventors that the difference in the measurement method particularly influences the values of the diameter of the quantum dots 131 and that the values measured by the TEM are less than the values measured by the AFM by about 15 nm.

Incidentally, the quantum dots including InAs may be formed on the GaAs cap layer 140, and moreover, the quantum dots are repeatedly covered with GaAs as described above, whereby the quantum dots including InAs may be multilayered.

The present invention is not limited to the aforementioned embodiments, but various changes may be made, if desired, without departing from the essence or spirit of the invention which can be read from the claims and the entire specification. A semiconductor apparatus manufacturing method and a semiconductor apparatus, which involve such changes, are also intended to be within the technical scope of the present invention.

### DESCRIPTION OF REFERENCE CODES

110 GaAs substrate

120 InAs layer

131 quantum dot

140 GaAs cap layer

200 MBE growth apparatus

211 substrate rotating and heating mechanism

212, 213, 214 evaporation source

1-9. (canceled)

10. A method of manufacturing a semiconductor apparatus in which a peak wavelength of PL emission is greater than or equal to 1.2 μm at a temperature of 300K, said method comprising:
a first forming process of forming a buffer layer including GaAs on a semiconductor substrate;
a second forming process of making quantum dots composed of InAs self-form on the formed buffer layer; and
a third forming process of forming a cap layer composed of GaAs to cover the formed quantum dots,
a second growth temperature being lower than a first growth temperature, the first growth temperature being a temperature in making the quantum dots self-form in said second forming process, the second growth temperature being a temperature in forming the cap layer in said third forming process, wherein
the first growth temperature is greater than or equal to 490° C. and less than or equal to 530° C.,
a growth rate of the quantum dots in said second forming process is greater than or equal to 0.02 ML/s and less than or equal to 0.4 ML/s,
the second growth temperature is greater than or equal to 420° C. and less than or equal to 480° C., and
a growth rate of the cap layer in said third forming process is greater than or equal to 0.1 ML/s and less than or equal to 0.5 ML/s.

11. The method of manufacturing the semiconductor apparatus according to claim 10, wherein an irradiance of an As molecular beam in said second forming process is 1×10⁻⁵ Torr.

12. The method of manufacturing the semiconductor apparatus according to claim 10, further comprising a temperature falling process of reducing a temperature of the semiconductor substrate at a rate of greater than or equal to 20° C./min and less than or equal to 35° C./min, after said second forming process and before said third forming process.

13. The method of manufacturing the semiconductor apparatus according to claim 10, wherein a diameter of the formed quantum dots is greater than or equal to 30 nm and less than or equal to 60 nm, and height of the formed quantum dots is less than or equal to 15 nm.

14. A semiconductor apparatus comprising quantum dots formed by the method of manufacturing the semiconductor apparatus according to claim 10.

15. A semiconductor apparatus comprising quantum dots formed by the method of manufacturing the semiconductor apparatus according to claim 11.
